(19) United States
(12) Patent Application Publication
(10) Pub. No.: US 2021/0337674 A1
(43) Pub. Date: Oct. 28, 2021

(54) ANODIC ALUMINUM OXIDE MOLD, MANUFACTURING METHOD THEREOF, HALF-FINISHED PROBE PRODUCT, MANUFACTURING METHOD THEREOF, PROBE CARD, AND MANUFACTURING METHOD THEREOF

(71) Applicant: POINT ENGINEERING CO., LTD., Asan (KR)

(72) Inventors: Bum Mo AHN, Suwon (KR); Seung Ho PARK, Hwaseong (KR); Tae Hwan SONG, Cheonan (KR)

(21) Appl. No.: 17/232,750

(22) Filed: Apr. 16, 2021

(30) Foreign Application Priority Data
Apr. 22, 2020 (KR) 10-2020-0048670

(51) Int. Cl. H05K 3/40; G01R 1/073

(52) U.S. Cl. CPC H05K 3/4015; G01R 1/07342; H05K 2203/0195; H05K 2203/041; H05K 2203/0338

(57) ABSTRACT

Proposed are an anodic aluminum oxide mold made of an anodic aluminum oxide film, a manufacturing method thereof, a half-finished probe product, a manufacturing method thereof, a probe card, and a manufacturing method thereof.

### CROSS REFERENCE TO RELATED APPLICATION

The present application claims priority to Korean Patent Application No. 10-2020-0048670, filed Apr. 22, 2020, the entire contents of which is incorporated herein for all purposes by this reference.

### BACKGROUND OF THE INVENTION

### Field of the Invention

The present disclosure relates to an anodic aluminum oxide mold made of an anodic aluminum oxide film, a manufacturing method thereof, a half-finished probe product, a manufacturing method thereof, a probe card, and a manufacturing method thereof.

### Description of the Related Art

In general, a semiconductor manufacturing process largely includes a fabrication process for forming a pattern on a wafer, an electrical die sorting (EDS) process for testing electrical characteristics of respective chips constituting the wafer, and an assembly process for assembling the wafer on which a pattern is formed to individual chips.

Here, the EDS process is performed to detect defective chips among the chips constituting the wafer. In the EDS process, a test device called a probe card which applies electrical signals to the chips constituting the wafer and determines whether the chips are defective on the basis of signals checked from the applied electrical signals is mainly used.

The probe card has probes each applying an electrical signal to each of the chips constituting the wafer by making contact with a pattern of the chip. Each of the probes is brought into contact with an electrode pad of each of devices on the wafer and measures electrical properties that are output when a specific current is applied thereto.

Depending on the structure of installing probes on a wiring substrate and the structure of the probes, the types of probe cards may be classified. As an example, a micro-electro-mechanical system (MEMS) probe card may have probes that are provided by performing a MEMS process on a side thereof having connection pads electrically connected to the probes.

An example of a patent that describes such a probe card is Korean Patent Application Publication No. 10-2000-0006268 (hereinafter referred to as ‘Patent Document 1’).

Patent Document 1 may have probes each composed of a vertical portion, a horizontal beam, and a tip portion and manufactured through a photolithography process.

In Patent Document 1, a thin metal layer is formed on a silicon substrate, a photoresist layer is formed on the thin metal layer, and then a mask is aligned on the photoresist layer so that the photoresist layer is exposed to ultraviolet light. After exposure to ultraviolet light, the photoresist covered by the mask is cured. Then, an exposed portion of the resist is dissolved and removed, thereby providing a photo mask layer. A probe (contactor in Patent Document 1) material is deposited on the dissolved and removed portion of the photo mask layer to form an interconnection trace. A thin metal layer is then plated on the interconnect trace, and a photo mask layer may be provided in the same manner as in the previous process. Thereafter, a probe material is deposited on a dissolved and removed portion of the photo mask layer, thereby forming the vertical portion of each of the probes. Subsequently, the above process may be repeatedly performed to form anther portion of each of the probes.

As such, in case of a MEMS probe card, the probes may be manufactured through a photolithography process on a silicon substrate, and then the probes may be joined to the side of the probe card where the connection pads are provided.

However, in order to manufacture the probes through the photolithography process on the silicon substrate, the manufacturing process is required to be performed as follows: a photoresist layer is provided to deposit the material of a portion (e.g., vertical portion) of each of the probes, a masking process is performed, and then a corresponding area is removed. Then, the above process is repeatedly performed to provide a remaining portion (e.g., vertical portion or horizontal beam) of each of the probes.

Therefore, since the same process is required to be repeatedly performed to form each portion constituting each of the probes, there is a disadvantage in that the manufacturing process is cumbersome and the manufacturing time is long.

As such, the MEMS process is a useful method for manufacturing a microstructure, but the manufacturing process is cumbersome because the microstructure is required to be manufactured through a series of steps.

The foregoing is intended merely to aid in the understanding of the background of the present disclosure, and is not intended to mean that the present disclosure falls within the purview of the related art that is already known to those skilled in the art.

### Documents of Related Art

(Patent document 1) Korean Patent No. 10-2000-0006268

### SUMMARY OF THE INVENTION

Accordingly, the present disclosure has been made keeping in mind the above problems occurring in the related art, and an objective of the present disclosure is to provide an anodic aluminum oxide mold that enables easy manufacturing of a microstructure, and a manufacturing method thereof.

Another objective of the present disclosure is to provide a half-finished probe product that can be easily manufactured using the above anodic aluminum oxide mold, and a manufacturing method thereof.

Still another objective of the present disclosure is to provide a probe card that can be easily manufactured using the above half-finished probe product, and a manufacturing method thereof.

In order to achieve the above objectives, according to one aspect of the present disclosure, there is provided an anodic aluminum oxide mold configured so that a plurality of unit anodic aluminum oxide sheets each having a through-hole are joined from top to bottom, and the respective through-holes of the unit anodic aluminum oxide sheets communicate with each other to define an internal space.

Furthermore, a surface of the anodic aluminum oxide mold may be configured as a barrier layer of each of the unit anodic aluminum oxide sheets.

Furthermore, each of the unit anodic aluminum oxide sheets may be composed of a plurality of anodic aluminum oxide layers joined by a junction layer.

According to another aspect of the present disclosure, there is provided a half-finished probe product, including: an anodic aluminum oxide mold configured so that a plurality of unit anodic aluminum oxide sheets each having a through-hole are joined from top to bottom, and the respective through-holes of the unit anodic aluminum oxide sheets communicate with each other to define an internal space; and a conductive material provided in the through-holes.

Furthermore, the half-finished probe product may further include: a conductive tip provided on a surface of the conductive material.

According to still another aspect of the present disclosure, there is provided a probe card, including: a multilayer wiring substrate made of an anodic aluminum oxide film, having a vertical wiring part and a horizontal wiring part therein, and having a probe connection pad on a surface thereof; and a body connected to the probe connection pad and configured as a single continuous body of a substantially same material.

According to still another aspect of the present disclosure, there is provided a method of manufacturing an anodic aluminum oxide mold, the method including: providing a plurality of unit anodic aluminum oxide sheets each having a through-hole; and joining the unit anodic aluminum oxide sheets from top to bottom so that the respective through-holes of the unit anodic aluminum oxide sheets communicate with each other to define an internal space.

According to still another aspect of the present disclosure, there is provided a method of manufacturing a half-finished probe product, the method including: providing a plurality of unit anodic aluminum oxide sheets each having a through-hole; joining the unit anodic aluminum oxide sheets from top to bottom so that the respective through-holes of the unit anodic aluminum oxide sheets communicate with each other to define an internal space; and simultaneously charging a conductive material configured as a metal paste or metal powder in the through-holes by pushing the conductive material from a first opening to a second opening of the through-holes.

Furthermore, the method may further include: providing a base plate having a conductive tip by forming a groove in the base plate, forming a temporary layer on a surface of the base plate, and charging the conductive material in the groove; connecting a first side of the conductive tip of the base substrate to the conductive material in the through-holes; and separating a second side of the conductive tip from the base substrate by removing the temporary layer of the base substrate.

According to still another aspect of the present disclosure, there is provided a method of manufacturing a probe card, the method including: providing a half-finished probe product by providing a plurality of unit anodic aluminum oxide sheets each having a through-hole, joining the unit anodic aluminum oxide sheets from top to bottom so that the respective through-holes of the unit anodic aluminum oxide sheets communicate with each other to define an internal space, thereby forming an anodic aluminum oxide mold, and simultaneously charging a conductive material configured as a metal paste or metal powder in the through-holes by pushing the conductive material from a first opening to a second opening of the through-holes; providing a multilayer wiring substrate by forming a vertical wiring part and a horizontal wiring part in an anodic aluminum oxide film and providing a probe connection pad on a surface of the anodic aluminum oxide film; positioning the half-finished probe product above the probe connection pad of the multilayer wiring substrate and joining a side of the conductive material in the through-holes to the probe connection pad; and removing the anodic aluminum oxide mold except for the conductive material.

The present disclosure can realize easy manufacturing of a microstructure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating an anodic aluminum oxide mold according to the present disclosure;

FIGS. 2A, 2B, and 2C are schematic views illustrating a process of manufacturing an anodic aluminum oxide mold according to the present disclosure;

FIG. 3 is a view schematically illustrating a process of manufacturing a half-finished probe product according to the present disclosure;

FIG. 4 is a view schematically illustrating a process of attaching a tip to the half-finished probe product according to the present disclosure;

FIGS. 5A and 5B are views illustrating a process of providing a probe on a multilayer wiring substrate by using the half-finished probe product according to the present disclosure;

FIGS. 6A and 6B are views illustrating a process of providing a probe on a multilayer wiring substrate by using a half-finished probe product according to another embodiment of the present disclosure; and

FIG. 7 is a view schematically illustrating a probe card according to the present disclosure.

### DETAILED DESCRIPTION OF THE INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses of films and regions and diameters of holes in the figures maybe exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing.

In describing various embodiments, the same reference numerals will be used throughout different embodiments and the description to refer to the same or like elements or parts. In addition, the configuration and operation already described in other embodiments will be omitted for convenience.

Hereinafter, exemplary embodiments of the present disclosure will be described in detail with reference to the accompanying drawings.

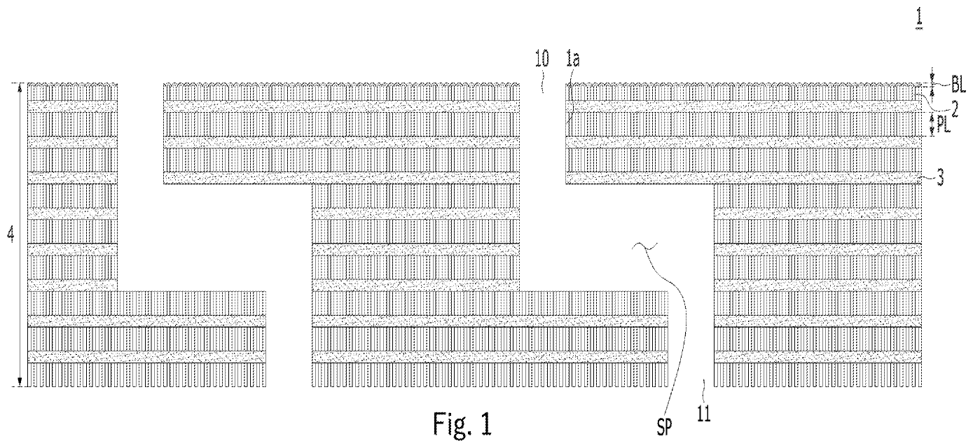

FIG. 1 is a view illustrating an anodic aluminum oxide mold 1 according to the present disclosure. As illustrated in FIG. 1, the anodic aluminum oxide mold 1 according to the present disclosure may have a structure in which a plurality of unit anodic aluminum oxide sheets 4 each having a through-hole 1a are joined from top to bottom, and the respective through-holes 1a of the unit anodic aluminum oxide sheets 4 communicate with each other to define an internal space SP.

The anodic aluminum oxide mold 1 may be composed of the plurality of unit anodic aluminum oxide sheets 4 joined in the upward and downward direction by a junction layer 3. Each of the unit anodic aluminum oxide sheets 4 may have the through-hole 1a therein. The unit anodic aluminum oxide sheets 4 may be stacked so that the respective through-holes 1a thereof communicate with each other. Therefore, the anodic aluminum oxide mold 1 may have the space SP formed therein as the through-holes 1a thereof communicate with each other.

By the provision of the space SP therein, the anodic aluminum oxide mold 1 may function as a frame for manufacturing a microstructure, such as a probe 40, provided on a probe card 30 (specifically, micro-electro-mechanical system (MEMS) probe card).

The anodic aluminum oxide mold 1 may be made of an anodic aluminum oxide film 2. The anodic aluminum oxide film 2 has a coefficient of thermal expansion of 2 to 3 ppm/° C. This may result in a small degree of deformation due to temperature. As an example, when functioning as the frame for manufacturing the probe 40, the anodic aluminum oxide mold 1a may be exposed to a high-temperature atmosphere for attaching the probe 40 to the probe card 30 (specifically, MEMS probe card). In this case, the anodic aluminum oxide mold 1 may not be easily thermally expanded under the high-temperature atmosphere for attaching the probe 40 to the probe card 30. This may prevent a problem of occurrence of a position error with respect to probe connection pads 16 of the probe card 30 to which probes 40 are attached.

In addition, since the anodic aluminum oxide mold 1 is made of the anodic aluminum oxide film 2, the internal space SP may be formed by performing an etching process. This may realize a fine pitch between spaces SP for providing microstructures which are required to become finer in size and pitch, for example, the probes 40.

As illustrated in FIG. 1, a surface of the anodic aluminum oxide mold 1 may be configured as a barrier layer BL of a unit anodic aluminum oxide sheet 4. The anodic aluminum oxide film 2 may include a porous layer PL formed by anodizing a metal and having regularly arranged pores P and a barrier layer BL formed under the porous layer PL to close one ends of the pores P.

The barrier layer BL configured to close one ends of the pores P may function as a shielding portion. This may prevent a problem in which fine particles are introduced and collected into the pores P in the surface of the anodic aluminum oxide mold 1.

In the present disclosure, although it is illustrated as an example that an upper surface of the anodic aluminum oxide mold 1 is configured as the barrier layer BL, the anodic aluminum oxide mold 1 may have a structure in which each of upper and lower surfaces thereof is configured as the barrier layer BL. In case where the upper and lower surfaces of the anodic aluminum oxide mold 1 are configured as the respective barrier layers BL that are symmetrical, the upper and lower surfaces of the anodic aluminum oxide mold 1 may have a uniform density. This may prevent warpage deformation due to heat from occurring.

The unit anodic aluminum oxide sheets 4 constituting the anodic aluminum oxide mold 1 may be joined together by the junction layer 3. The junction layer 3 may be a photosensitive material capable of a photolithography process, and may be a dry film photoresist (DFR) as an example. Meanwhile, the junction layer 3 may be a thermosetting resin. In this case, examples of the thermosetting resin may include polyimide resin, polyquinoline resin, polyamideimide resin, epoxy resin, polyphenylene ether resin, fluororesin, and the like.

The joining of the unit anodic aluminum oxide sheets 4 joined by the junction layer 3 may be performed by a suitable method of joining the unit anodic aluminum oxide sheets 4.

The anodic aluminum oxide mold 1 may be manufactured by a manufacturing method, including providing the unit anodic aluminum oxide sheets 4 each having the through-hole 1a formed by the etching process, and joining the unit anodic aluminum oxide sheets 4 from top to bottom so that the respective through-holes 1a of the unit anodic aluminum oxide sheets 4 communicate with each other to define the internal space SP.

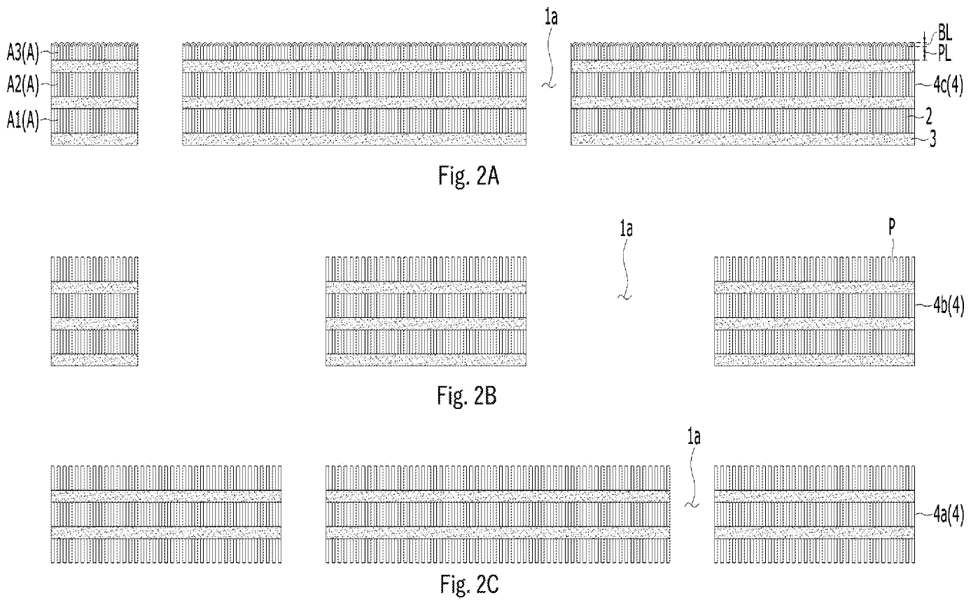

FIGS. 2A, 2B, and 2C are schematic views illustrating a process of manufacturing an anodic aluminum oxide mold 1 according to the present disclosure. As an example, the anodic aluminum oxide mold 1 may be composed of a first unit anodic aluminum oxide sheet 4a, a second unit anodic aluminum oxide sheet 4b, and a third unit anodic aluminum oxide sheet 4c that are sequentially stacked.

FIGS. 2A to 2C sequentially illustrate the third unit anodic aluminum oxide sheet 4c, the second unit anodic aluminum oxide sheet 4b, and the first unit anodic aluminum oxide sheet 4a constituting the anodic aluminum oxide mold 1.

As illustrated in FIGS. 2A to 2C, a unit anodic aluminum oxide sheet 4 may be composed of a plurality of anodic aluminum oxide layers A joined by a junction layer 3. By such a structure in which the plurality of anodic aluminum oxide layers A are stacked, durability of the unit anodic aluminum oxide sheet 4 may be improved. In addition, a plurality of unit anodic aluminum oxide sheets 4 may be stacked, so that durability of the anodic aluminum oxide mold 1 according to the present disclosure may be improved.

First, FIG. 2A illustrates the third unit anodic aluminum oxide sheet 4c forming a surface of the anodic aluminum oxide mold 1 according to the present disclosure. The third unit anodic aluminum oxide sheet 4c may include an anodic aluminum oxide layer A having an upper surface configured as a barrier layer BL. In this case, by the third unit anodic aluminum oxide sheet 4c forming an upper surface of the anodic aluminum oxide mold 1, the upper surface of the anodic aluminum oxide mold 1 may be configured as the barrier layer BL.

As illustrated in FIGS. 2A, the third unit anodic aluminum oxide sheet 4c may be composed of a plurality of anodic aluminum oxide layers A joined by a junction layer 3.

The junction layer 3 for joining the plurality of anodic aluminum oxide layers A may the same as a junction layer 3 for joining the unit anodic aluminum oxide sheets 4 constituting the anodic aluminum oxide mold 1.

Among the plurality of anodic aluminum oxide layers A constituting the third unit anodic aluminum oxide sheet 4c, an anodic aluminum oxide layer A forming a surface of the third unit anodic aluminum oxide sheet 4c may be configured as an anodic aluminum oxide film 2 including a porous layer PL and a barrier layer BL.

The anodic aluminum oxide layer A may have the junction layer 3 on at least a side thereof, so that the plurality of anodic aluminum oxide layers A may be joined by the junction layer 3. In the present disclosure, as an example, the junction layer 3 may be provided under the anodic aluminum oxide film 2 forming the anodic aluminum oxide layer A, thereby joining the anodic aluminum oxide layers A.

The junction layer 3 may be provided under the anodic aluminum oxide film 2 to define an etching region for forming a through-hole 1a. As an example, the third unit anodic aluminum oxide sheet 4c may be configured by sequentially stacking a first anodic aluminum oxide layer A1, a second anodic aluminum oxide layer A2, and a third anodic aluminum oxide layer A3. In this case, the third anodic aluminum oxide layer A3 may form a surface of the third unit anodic aluminum oxide sheet 4c, and thus may be configured as an anodic aluminum oxide film 2 including a porous layer PL and a barrier layer BL.

A junction layer 3 may be provided on a lower surface of the third anodic aluminum oxide layer A3. Then, at least a portion of the junction layer 3 may be patterned by a lithography process. A patterned region removed by patterning may function as a region for forming the through-hole 1a. In other words, the through-hole 1a may be formed in the third anodic aluminum oxide layer A3 by etching the third anodic aluminum oxide layer A3 through the region removed by patterning.

Then, the junction layer 3 may be provided on a lower surface of the anodic aluminum oxide film 2 without removal to perform a joining function through an unpatterned region. On a lower surface of the second anodic aluminum oxide layer A2 joined to a lower portion of the third anodic aluminum oxide layer A3 by the junction layer 3, a junction layer 3 may be provided. Then, at least a portion of the junction layer 3 may be patterned by a lithography process, and a patterned region may be etched thereby forming a through-hole 1a. A junction layer 3 may also be provided on a lower surface of the first anodic aluminum oxide layer A1. Then, in the same manner as above, at least a portion of the junction layer 3 maybe patterned by a lithography process, and a patterned region may be etched thereby forming a through-hole 1a.

In this case, the respective patterned regions of the junction layers 3 provided on the lower surfaces of the first to third anodic aluminum oxide layers A1, A2, and A3 may correspond to each other. As a result, the respective through-holes 1a may be formed in the same position. These through-holes 1a may communicate with each other at the same position while having the same diameter, thereby defining one through-hole 1a through the first to third anodic aluminum oxide layers A1, A2, and A3. Such a process may be a step of providing the unit anodic aluminum oxide sheet 4 in which the through-hole 1a is formed by etching.

The second unit anodic aluminum oxide sheet 4b and the first unit anodic aluminum oxide sheet 4a illustrated in FIGS. 2B and 2C may also be manufactured by the above step of providing the unit anodic aluminum oxide sheet 4.

Then, the unit anodic aluminum oxide sheets 4a, 4b, and 4c may be joined from top to bottom so that the respective through-holes 1a of the unit anodic aluminum oxide sheets 4a, 4b, and 4c communicate with each other to define an internal space SP. Specifically, the first to third unit anodic aluminum oxide sheets 4a, 4b, and 4c may be stacked so that the through-holes 1a of thereof 4c are connected to each other in communication with each other. Then, the stacked unit anodic aluminum oxide sheets 4a, 4b, and 4c may be joined to each other by unpatterned regions of the junction layers 3 to form the anodic aluminum oxide mold 1.

In the foregoing description, although it has been described that etching is performed on each of the patterned regions of the first to third anodic aluminum oxide layers A, the process of forming the through-holes 1a by etching the patterned regions is not limited thereto. For example, each of the anodic aluminum oxide layers A with the junction layer 3 thereon may be patterned, then, instead of performing etching immediately, the remaining anodic aluminum oxide layers A stacked thereon may be provided, and finally the corresponding patterned regions between the anodic aluminum oxide layers A may be etched simultaneously. As a result, the formation of the through-holes 1a that are continuously connected to each other may be performed simultaneously.

As described in the method of manufacturing the anodic aluminum oxide mold 1, the junction layer 3 for joining the anodic aluminum oxide layers A and joining the unit anodic aluminum oxide sheets 4 may simultaneously perform a function of providing a space for forming the through-hole 1a, and a function of joining the anodic aluminum oxide layers A and joining the unit anodic aluminum oxide sheets 4. Therefore, the junction layer 3 is preferably configured to simultaneously possess photosensitive properties, and properties as a joining material for the purposes of being patterned by a photoresist process and of performing a joining function.

The anodic aluminum oxide mold 1 according to the present disclosure may have the space SP formed therein by a structure in which the through-holes 1a continuously communicate with each other. As an example, the anodic aluminum oxide mold 1 may be used to manufacture a microstructure, such as a probe 40, composed of a single continuous body by charging a conductive material in the space SP.

In case where the conductive material 6 is charged in the internal space SP of the anodic aluminum oxide mold 1, a microstructure half-finished product including the conductive material 6 therein, such as a half-finished probe product 20, may be formed. Hereinafter, the microstructure half-finished product is exemplified and described as the half-finished probe product 20.

The half-finished probe product 20 may include the anodic aluminum oxide mold 1 having a structure in which the unit anodic aluminum oxide sheets 4 each having the through-hole 1a are joined from top to bottom, and the respective through-holes 1a of the unit anodic aluminum oxide sheets 4 communicate with each other to define the internal space SP; and the conductive material 6 charged in the through-holes 1a.

The half-finished probe product 20 may function to temporarily store the probe 40 therein before joining the probe 40 to a probe connection pad 16 of a probe card 30.

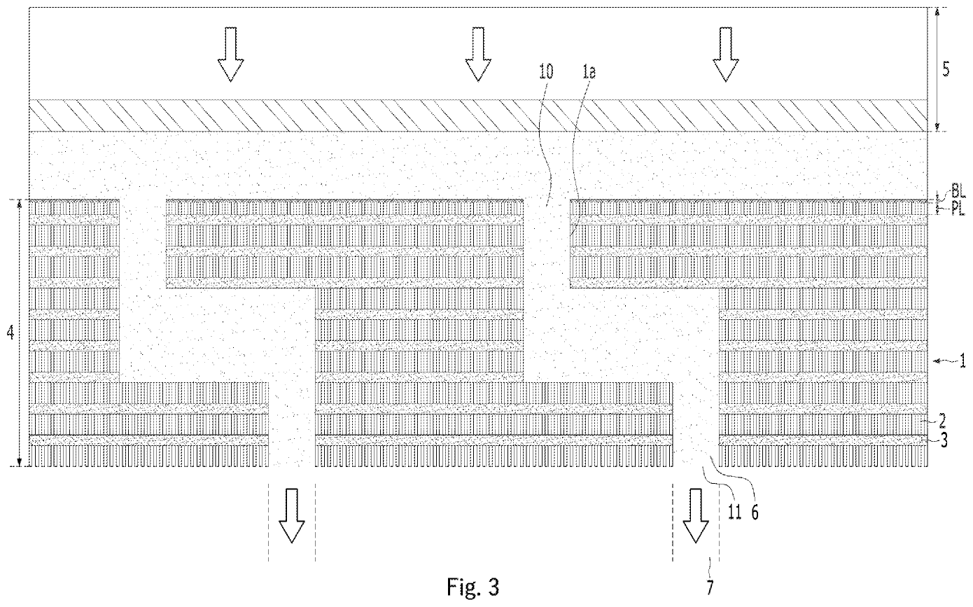

FIG. 3 is a view schematically illustrating a process of manufacturing a half-finished probe product 20 according to the present disclosure. The manufacturing process below may be equally applied to a process of manufacturing a microstructure half-finished product other than the half-finished probe product 20.

The half-finished probe product 20 may be manufactured by a method of manufacturing a probe, the method including: providing a plurality of unit anodic aluminum oxide sheets 4 each having a through-hole 1a; joining the unit anodic aluminum oxide sheets 4 from top to bottom so that the respective through-holes 1a of the unit anodic aluminum oxide sheets 4 communicate with each other to define an internal space SP; and simultaneously charging a conductive material 6 configured as a metal paste or metal powder in the through-holes 1a by pushing the conductive material 6 from a first opening 10 to a second opening 11 of the through-holes 1a.

As illustrated in FIG. 3, the internal space SP of an anodic aluminum oxide mold 1 may be formed by continuously connecting the respective through-holes 1a of the unit anodic aluminum oxide sheets 4 to communicate with each other. The internal space SP in the anodic aluminum oxide mold 1 may be defined by the continuous through-holes 1a.

Here, the first opening 10 is a through-hole 1a of a third unit anodic aluminum oxide sheet 4c located at an upper side of the anodic aluminum oxide mold 1, and the second opening 11 is a through-hole 1a of a first unit anodic aluminum oxide sheet 4a located at a lower side of the anodic aluminum oxide mold 1.

The conductive material 6 may be configured as a metal paste or metal powder. The conductive material 6 of this type may be charged in the respective through-holes 1a of the anodic aluminum oxide mold 1 while flowing from the first opening 10 to the second opening 11 of the through-holes 1a by a pressing means 5.

As illustrated in FIG. 3, the pressing means 5 may be provided above the anodic aluminum oxide mold 1. In this case, the pressing means 5 may be configured as a means suitable for pushing the conductive material 6 configured as the metal paste or metal powder and simultaneously charging the conductive material 6 in the through-holes 1a of the anodic aluminum oxide mold 1.

The first opening 10 of the anodic aluminum oxide mold 1 may function as an inlet for allowing introduction of the conductive material 6. The conductive material 6 may be simultaneously charged from the first opening 10 to the second opening 11 of the anodic aluminum oxide mold 1 by the pressing means 5. The pressing means 5 may push the conductive material 6 to be introduced into the first opening 10, and then cause the conductive material 6 to flow to the second opening 11 by exerting a continuous pushing force thereon.

In this case, since the through-holes 1a of the anodic aluminum oxide mold 1 may be continuously formed, the conductive material 6 may be simultaneously charged therein by the pressing means 5.

As illustrated in FIG. 3, the through-holes 1a of the unit anodic aluminum oxide sheets 4a, 4b, and 4c of the anodic aluminum oxide mold 1 may have different inner diameters and may communicate with each other. Such a structure may be a structure in consideration of elastic deformation of a microstructure, such as a body BD of a probe 40, formed by charging the conductive material 6 in the through-holes 1a.

In this case, an auxiliary charging means 7 may be provided below the second opening 11 of the through-holes 1a having different inner diameters and communicating with each other. The auxiliary charging means 7 may enable the conductive material 6 to be charged more quickly and efficiently in the through-holes 1a in the process of charging the conductive material 6 therein with the pressing means 5. As an example, the auxiliary charging means 7 may be a means using suction force or vacuum pressure.

The auxiliary charging means 7 may be provided so as to correspond to each of second openings 11 of a plurality of through-holes 1a provided in the anodic aluminum oxide mold 1.

The auxiliary charging means 7 may be configured as a vacuum chamber below the second opening 11 of the through-holes 1a. The auxiliary charging means 7 may generate a vacuum pressure below the second opening 11 of the through-holes 1a, so that the conductive material 6 is efficiently and simultaneously charged from the first opening 10 to the second opening 11 of the through-holes 1a.

Therefore, in the present disclosure, in order to perform a simultaneous charging process more quickly and efficiently than when simultaneously charging the conductive material 6 in the through-holes 1a using the pressing means 5 in the structure of the through-holes 1a considering elastic deformation of the probe 40, the auxiliary charging means 7 may be provided at a position opposite to the pressing means 5.

When the conductive material 6 charged in the through-holes 1a is configured as the metal paste, the charging process may be followed by a curing and annealing process.

Meanwhile, when the conductive material 6 charged in the through-holes 1a is configured as the metal powder, the charging process may be followed by a sintering process.

Therefore, in the present disclosure, after simultaneously charging the conductive material 6 in the continuous through-holes 1a of the anodic aluminum oxide mold 1, curing, annealing, or sintering may be performed depending on the type of the conductive material 6. In other words, the conductive material 6 forming the body BD of the probe 40 may be simultaneously charged, followed by a post-treatment process thereby simultaneously manufacturing the body BD.

Conventionally, a process of manufacturing a probe includes forming each portion (e.g., vertical portion and horizontal beam) constituting a probe 40, and then performing a post-plating process for each portion, which is cumbersome. In addition, the same process is required to be repeatedly performed, which may extend manufacturing time, resulting in a problem of a low production speed However, in the present disclosure, by using the anodic aluminum oxide mold 1 having the continuous through-holes 1a to simultaneously charge the conductive material 6 in the through-holes 1a and by performing a single post-treatment process to manufacture the body BD of the probe 40, there is an advantage in terms of production speed and efficiency.

The probe 40 may be elastically deformed, and may perform scrubbing while an end of thereof moves on an electrode pad WP of a wafer W. By such scrubbing, an oxide film on a surface of the electrode pad WP may be removed and contact resistance may be reduced thereby. In order to perform this function, the probe 40 may include a conductive tip 9 at the end thereof. In order to perform scrubbing, the conductive tip 9 may have a sharp shape.

The conductive tip 9 may be manufactured separately from the body BD of the probe 40 and then provided.

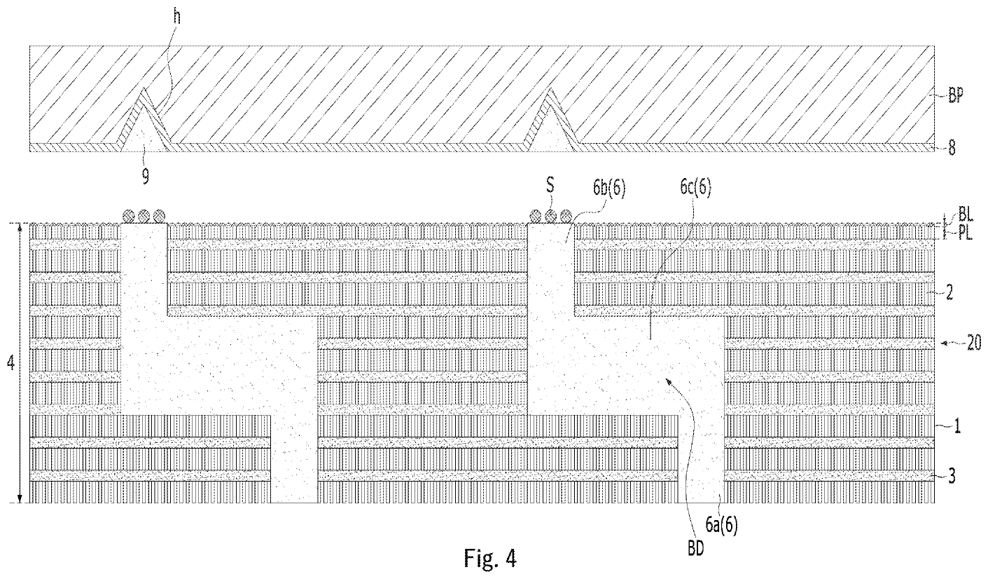

As illustrated in FIG. 4, the conductive tip 9 may be provided on a surface of the conductive material 6 charged in the through-holes 1a of the anodic aluminum oxide mold 1.

The method of manufacturing the half-finished probe product 20 may further include: providing a base plate BP having the conductive tip 6 by forming a groove h in the base plate BP, forming a temporary layer 8 on a surface of the base plate BP, and charging the conductive material 6 in the groove h; connecting a first side of the conductive tip 9 of the base substrate BP to the conductive material 6 in the through-holes 1a; and separating a second side of the conductive tip 9 from the base substrate BP by removing the temporary layer 8 of the base substrate BP by an etching process.

First, as described above, the conductive material 6 may be provided in the half-finished probe product 20 by being simultaneously charged in the through-holes 1a of the anodic aluminum oxide mold 1 by being pushed by the pressing means 5.

Then, the base substrate BP having the conductive tip 9 may be provided. Preferably, the conductive tip 9 is provided on the base plate BP by providing the temporary layer 8 on the surface of the base substrate BP having the sharp groove h, and then charging the conductive material 6 in the groove h.

The temporary layer 8 may be electrically conductive, and may function as an anode or a cathode for an electroplating treatment so that the conductive material 6 for forming the probe 40 is electroplated on the temporary layer 8. Examples of the material of the temporary layer 8 may include aluminum, copper, gold, titanium, tungsten, silver, and alloys thereof. Preferably, the temporary layer 8 is made of copper.

The temporary layer 8 maybe deposited by any suitable method including chemical vapor deposition, physical vapor deposition, sputter deposition, electroless plating, electron beam deposition, and thermal evaporation.

The deposition of the conductive tip 9 may be performed by electroplating the material of the conductive tip 9 or by any other suitable method (e.g., chemical vapor deposition, physical vapor deposition, sputter deposition, electroless plating, electron beam deposition, and thermal deposition). In this case, the material of the conductive tip 9 may be a suitable material including palladium, gold, rhodium, nickel, cobalt, silver, platinum, conductive nitride, conductive carbide, tungsten, titanium, molybdenum, rhenium, indium, osmium, rhodium, copper, refractory metals, alloys thereof, and combinations thereof, but is not limited thereto.

As illustrated in FIG. 4, as an example, the base substrate BP having the conductive tip 9 may be positioned at an upper position corresponding to the first opening 10.

As an example, a solder S may be provided on a surface of the conductive material 6 charged in the anodic aluminum oxide mold 1. In the present disclosure, the solder S is provided to connect the conductive material 6 to the conductive tip 9, but the method for connecting the conductive tip 9 to the conductive material 6 is not limited thereto. As another example, a eutectic bonding method may be used. In this case, a eutectic bonding layer made of a combination of Ni/Sn, Ag/Sn/Cu, Ag/Sn, Cu/Sn, Au/Sn, etc. may be provided on the surface of the conductive material 6. Hereinafter, it will be described as an example that the conductive tip 9 is connected to the conductive material 6 by using the solder S.

The solder S may be configured to electrically connect and join the conductive material 6 and the conductive tip 9 to each other. Therefore, the solder S may be provided on at least a surface of the conductive material 6 or the conductive tip 9. The solder S may be provided on an upper surface of the conductive material 6 as an example.

When the conductive material 6 and the conductive tip 9 are joined to each other by the solder S, the temporary layer 8 of the base substrate BP may be removed through an etching process. Therefore, ends of the conductive tip 9 may be simultaneously separated from the base substrate BP.

As an example, when the temporary layer 8 is made of copper, etchant used in the etching process may be a copper etchant. Since the anodic aluminum oxide mold 1 according to the present disclosure may be made of an anodic aluminum oxide film 2, the anodic aluminum oxide mold 1 may have corrosion resistance to the copper etchant. Therefore, even if the temporary layer 8 is removed using the copper etchant and the conductive tip 9 is separated from the base substrate BP, the anodic aluminum oxide mold 1 may not be chemically etched. In addition, since a surface of the anodic aluminum oxide mold 1 may be configured as a barrier layer BL, the surface thereof may have relatively high chemical corrosion resistance.

As result, in the method of manufacturing the half-finished probe product 20 according to the present disclosure, by removing the temporary layer 8 without damage to the surface of the anodic aluminum oxide mold 1 due to the etchant, the conductive tip 9 may be simultaneously provided on to the body BD of the probe 40.

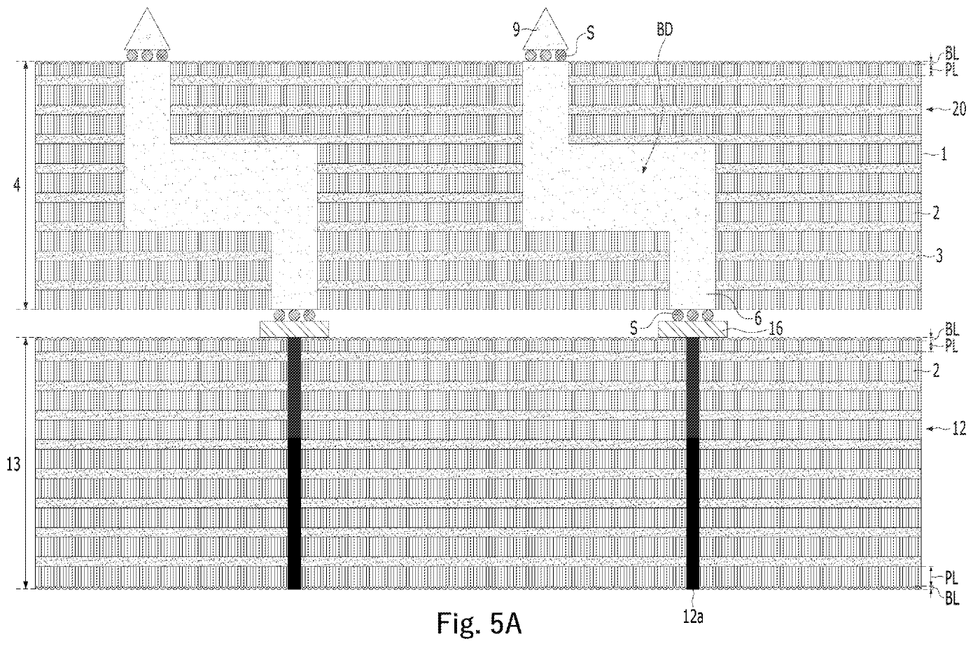

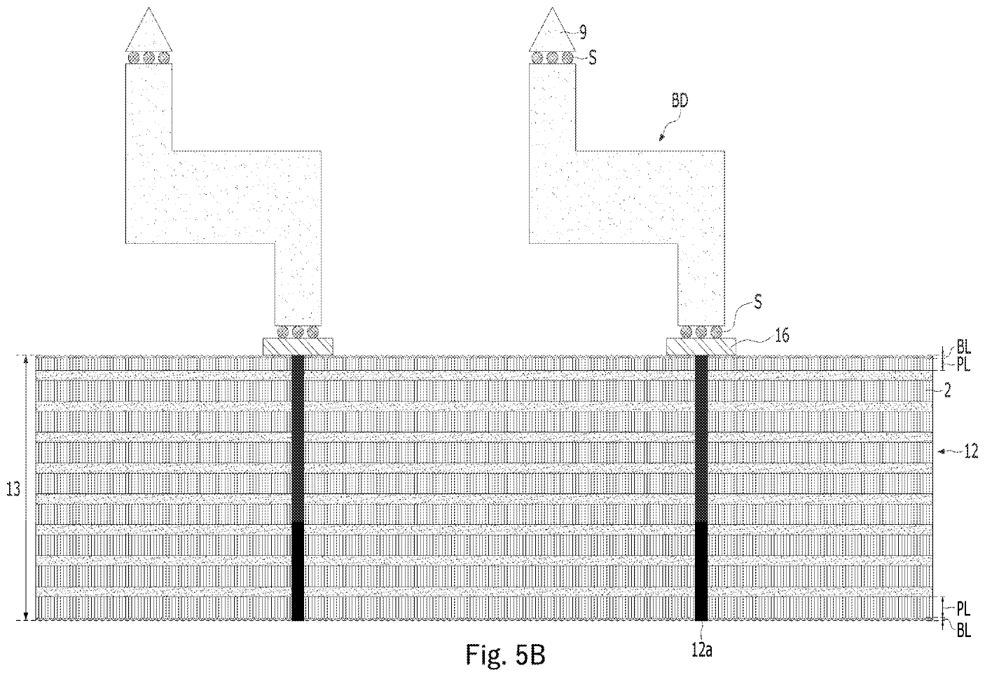

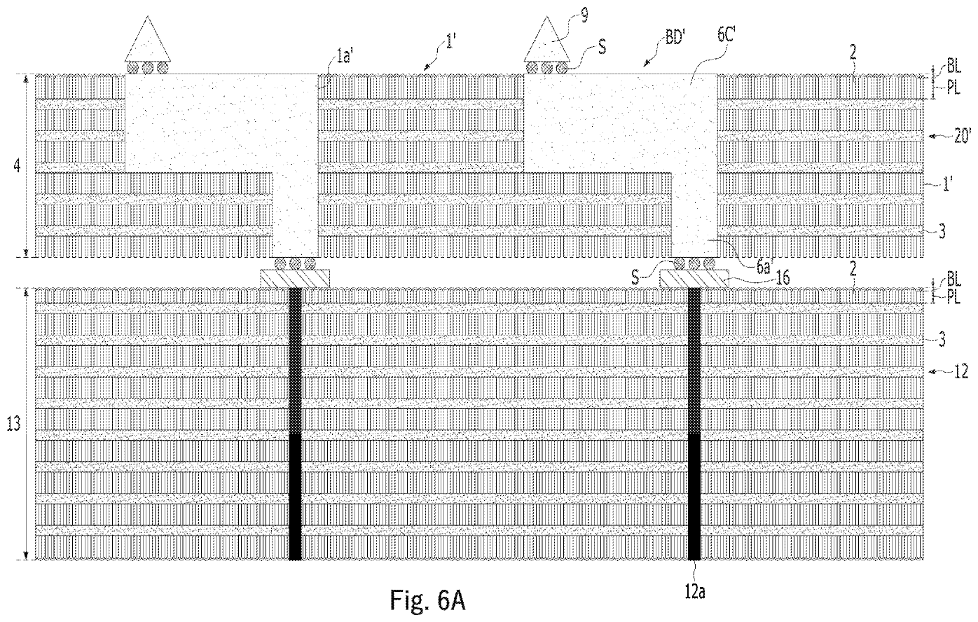

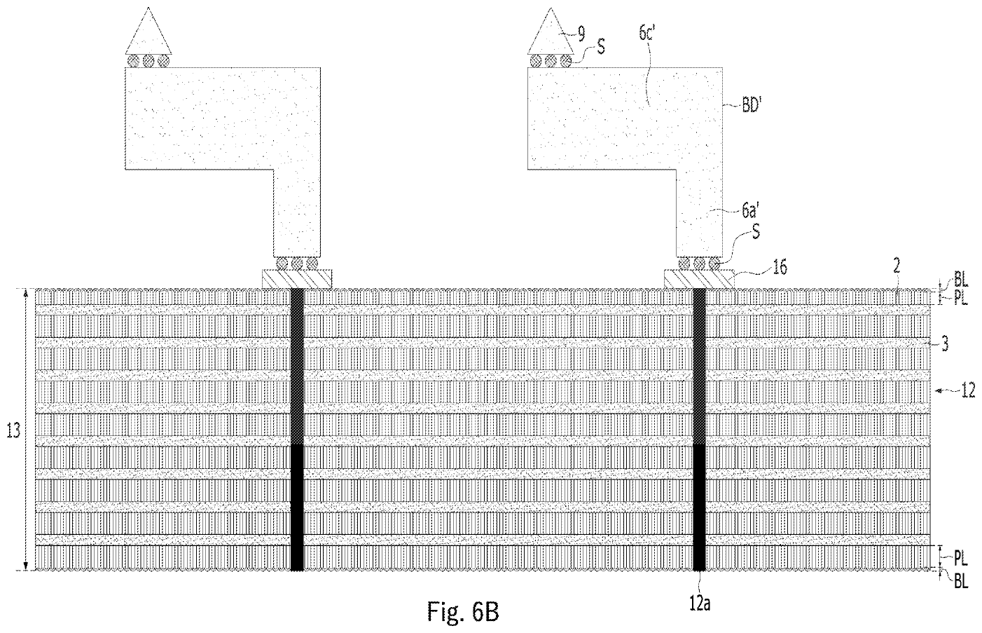

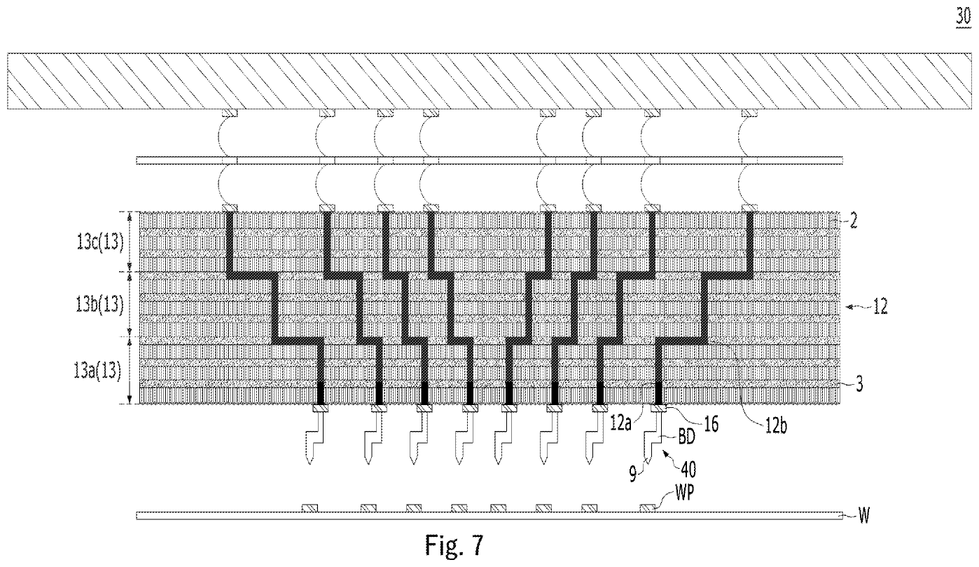

FIGS. 5A and 5B are enlarged views illustrating a process of joining a probe 40 to a multilayer wiring substrate 12 constituting a probe card 30 according to the present disclosure using the half-finished probe product 20 according to the present disclosure; FIGS. 6A and 6B are enlarged views illustrating a process of joining a probe 40 to a multilayer wiring substrate 12 using a half-finished probe product 20 according to another embodiment; and FIG. 7 is a view schematically illustrating the probe card 30 according to the present disclosure.

As illustrated in FIG. 7, the probe card 30 according to the present disclosure may include the multilayer wiring substrate 12 made of an anodic aluminum oxide film 2, having a vertical wiring part 12a and a horizontal wiring part 12b therein, and having a probe connection pad 16 on a surface thereof; and a body BD connected to the probe connection pad 16 and configured as a single continuous body of the substantially same metal material.

The multilayer wiring substrate 12 may be made of the anodic aluminum oxide film 2, and thus has an advantage of undergoing a small degree of thermal deformation under a high-temperature environment. The multilayer wiring substrate 12 maybe configured by stacking a plurality of unit anodic aluminum oxide wiring substrates 13 from top to bottom. The unit anodic aluminum oxide wiring substrates 13 may be joined by a junction layer 3 to form the multilayer wiring substrate 12.

The multilayer wiring substrate 12 may be manufactured and provided through various manufacturing methods. As an example, one unit anodic aluminum oxide wiring substrate 13 maybe provided in a structure in which a plurality of anodic aluminum oxide films 2 are stacked. In the present disclosure, as an example, the multilayer wiring substrate 12 may include a first unit anodic aluminum oxide wiring substrate 13a, a second unit anodic aluminum oxide wiring substrate 13b, and a third unit anodic aluminum oxide wiring substrate 13c. The second and third unit anodic aluminum oxide wiring substrates 13b and 13c may be sequentially stacked on the first unit anodic aluminum oxide wiring substrate 13a. However, the number of the stacked unit anodic aluminum oxide wiring substrates 13a, 13b, and 13c is not limited to three, but may be several tens.

Each of the first to third unit anodic aluminum oxide wiring substrates 13a, 13b, and 13c may have a structure in which a plurality of anodic aluminum oxide films 2 are stacked and joined by a junction layer 3. Each of the unit anodic aluminum oxide wiring substrates 13a, 13b, and 13c may have a vertical wiring part 12a therein.

A method of manufacturing a multilayer wiring substrate 12 according to an embodiment includes the following steps.

First, in a plurality of anodic aluminum oxide films 2 joined by a junction layer 3 and constituting a unit anodic aluminum oxide wiring substrate 13, a through-hole 1a may be formed by an etching process. In this case, by the etching process, the though-hole 1a may have an inner wall vertical in a straight line. This may facilitate formation of a plurality of fine pitch through-holes 1a in the anodic aluminum oxide films 2. Each of the through-holes 1a may have a diameter larger than that of each of pores P of the anodic aluminum oxide films 2.

Then, a vertical wiring part 12a may be formed in each of the through-holes 1a.

The vertical wiring part 12a may be formed by charging a metal material in the through-hole 1a. The metal material charged in the through-hole 1a may be a low-resistance metal material including at least one of Au, Ag, and Cu. In case of forming the vertical wiring part 12a by charging the low-resistance metal material having the above component in the through-hole 1a, wiring resistance is low, which may improve transmission speed of electric signals. As a result, it may be more advantageous in an electrical test of a semiconductor chip using the probe card 30.

Then, a junction layer 3 maybe formed on the anodic aluminum oxide films 2. The junction layer 3 may be a photosensitive material, and may be made of the same material as the material of a junction layer 3 used in an anodic aluminum oxide mold 1. Specifically, the junction layer 3 may have both photosensitive properties, and properties as a joining material.

The junction layer 3 may be provided between a plurality of unit anodic aluminum oxide wiring substrates 13 to join the unit anodic aluminum oxide wiring substrates 13 to each other.

At least a portion of the junction layer 3 may then be patterned. The junction layer 3 may be patterned to allow a horizontal wiring part 12b to be provided on an upper surface of an anodic aluminum oxide film 2 forming a surface of each of the unit anodic aluminum oxide wiring substrates 13 so as to be connected to each of the respective vertical wiring parts 12a. As a result of patterning the junction layer 3, an upper surface of each of the vertical wiring parts 12a may be exposed.

The patterning of the junction layer 3 may form a patterned region defining a space for forming each of the respective horizontal wiring parts 12b in the unit anodic aluminum oxide wiring substrate 13. After forming the space for forming the horizontal wiring part 12b by patterning, the junction layer 3 may remain on the upper surface of the anodic aluminum oxide film 2 without removal. Then, the junction layer 3 may perform a joining function by an unpatterned region thereof.

As such, the junction layer 3 for joining the unit anodic aluminum oxide wiring substrates 13 may simultaneously perform a function of providing the space for forming the horizontal wiring part 12b and the joining function.

The multilayer wiring substrate 12 according to the present disclosure may have a structure in which both the junction layer 3 and the horizontal wiring part 12b are provided on the same plane at a junction interface between the unit anodic aluminum oxide wiring substrates 13. Such a structure may improve joining strength and durability of the multilayer wiring substrate 12 by preventing a gap between the unit anodic aluminum oxide wiring substrates 13.

The multilayer wiring substrate 12 may have upper and lower surfaces configured as barrier layers BL. Such a structure may reduce a difference in density between the upper and lower surfaces of the multilayer wiring substrate 12, thereby minimizing a problem of warpage deformation due to heat.

In addition, since the upper and lower surfaces of the multilayer wiring substrate 12 may have a closed structure due to the barrier layers BL, this may prevent a problem in which particles are introduced into the multilayer wiring substrate 12.

A probe connection pad 16 connected to each of probes 40 may be provided on a surface of the multilayer wiring substrate 12. Since the upper and lower surfaces of the multilayer wiring substrate 12 may be configured as the barrier layers BL, the probe connection pad 16 may be provided on a surface of an associated one of the barrier layers BL.

A method of manufacturing a probe card 30 according to the present disclosure may include: providing a half-finished probe product 20 by providing a plurality of unit anodic aluminum oxide sheets 4 each having a through-hole 1a, by joining the unit anodic aluminum oxide sheets from top to bottom so that the respective through-holes 1a of the unit anodic aluminum oxide sheets communicate with each other to define an internal space, thereby forming an anodic aluminum oxide mold 1, and simultaneously charging a conductive material 6 configured as a metal paste or metal powder in the through-holes 1a by pushing the conductive material 6 from a first opening 10 to a second opening 11 of the through-holes 1a; providing a multilayer wiring substrate 12 by forming a vertical wiring part 12a and a horizontal wiring part 12b in an anodic aluminum oxide film 2 and providing a probe connection pad 16 on a surface of the anodic aluminum oxide film 2; positioning the half-finished probe product 20 above the probe connection pad 16 of the multilayer wiring substrate 12 and joining a side of the conductive material 6 in the through-holes 1a to the probe connection pad 16; and removing the anodic aluminum oxide mold 1 except for the conductive material 6.

Since the providing of the half-finished probe product 20 remains the same as the description with reference to FIGS. 3 and 4, the above description will be referred to. Hereinafter, a process of joining a probe 40 to the probe connection pad 16 using the half-finished probe product 20 and providing the probe 40 on the probe card 30 will be described in detail below with reference to FIGS. 5A, 5B, 6A and 6B.

As illustrated in FIG. 5A, the half-finished probe product 20 may be positioned above the multilayer wiring substrate 12 so that the probe connection pad 16 and the conductive material 6 correspond to each other. Then, a side of the conductive material 6 may be brought into contact with a solder provided on the probe connection pad 16 and joined to the probe connection pad 16.

Thereafter, as illustrated in FIG. 5B, the anodic aluminum oxide mold 1 except for the conductive material 6 may be removed by an etching process.

In this case, the multilayer wiring substrate 12 may have a structure in which upper and lower surfaces thereof are configured as barrier layers BL, and the probe connection pad 16 is provided on a surface of an associated one of the barrier layers BL. The barrier layer BL may have a higher density than a porous layer PL and thus may have relatively strong corrosion resistance to etchant. With such a structure, surface damage of the multilayer wiring substrate 12 may not occur in the etching process for removing the anodic aluminum oxide mold 1.

As a result of removing the anodic aluminum oxide mold 1, the probe card 30 may have a body BD connected to the probe connection pad 16 and configured as a single continuous body of the substantially same metal material. Specifically, the body BD may be a body BD of the probe 40.

The body BD of the probe 40 according to the present disclosure may be formed by simultaneously charging the conductive material 6 in the continuous through-holes 1a of the anodic aluminum oxide mold 1 by pushing the conductive material 6 using a pressing means 5. Therefore, the body BD may have a continuous shape in which vertical portions and a horizontal portion made of the same metal material are continuously connected to each other.

The body BD of the probe 40 is not limited in its shape as long as it has a shape in which portions of the same metal material are continuously connected to each other. FIGS. 6A and 6B illustrate a process of joining a body BD′ having a shape different from that of the body BD of the probe 40 illustrated in FIG. 7 to a multilayer wiring substrate 12 using a half-finished probe product 20′ according to another embodiment.

As illustrated in FIG. 6A, the half-finished probe product 20′ may include an anodic aluminum oxide mold 1′ having a through-hole 1a′ and a conductive material 6 charged in the through-hole 1a′.

The conductive material 6 may have a shape in which a vertical portion 6a′ having a side joined to a probe connection pad 16 and a horizontal portion 6c′ having a side to which a conductive tip 9 is joined are continuously connected to each other. As illustrated in FIGS. 5A and 5B, as an example, the conductive material 6 of the probe semi-finished product 20 according to the embodiment of the present disclosure may have a shape in which a first vertical portion 6a having a side joined to the probe connection pad 16, a second vertical portion 6b having a side to which the conductive tip 9 is joined, and an intermediate portion 6c connecting the first and second vertical portions 6a and 6b to each other. Therefore, the half-finished probe product 20′ according to another embodiment illustrated in FIGS. 6A and 6B differs from the half-finished probe product 20 in that the conductive material 6 is composed of the vertical portion 6a′ and the horizontal portion 6c′.

In the half-finished probe product 20′ having the conductive material 6 having such a structure, a side of the conductive material 6 may be joined to the multilayer wiring substrate 12 by a solder S or a eutectic bonding layer provided on the probe connection pad 16. The process of joining the side of the conductive material 6 remains the same as the process with reference to FIG. 5A. Therefore, a detailed description thereof will be omitted by referring to the above description with reference to FIGS. 5A and 5B.

As illustrated in FIG. 6B, the half-finished probe product 20′ with the side of the conductive material 6 joined to the multilayer wiring substrate 12 may be subjected to a process of removing the anodic aluminum oxide mold 1 except for the conductive material 6. The anodic aluminum oxide mold 1 may be removed by an etching process. The process of removing the anodic aluminum oxide mold 1 except for the conductive material 6 by the etching process maybe performed in the same manner as the process with reference to FIG. 5B.

As such, the anodic aluminum oxide mold 1 according to the present disclosure may be used to manufacture a fine pitch microstructure, and through the process of charging a material (metal or non-metal) in the through-hole 1a formed in the anodic aluminum oxide mold 1, a microstructure half-finished product may be manufactured precisely and easily. In addition, the anodic aluminum oxide mold 1 may be used to manufacture the probe 40 of the probe card 30.

The probe card 30 according to the present disclosure may include the probe 40 having the body BD that is configured as a single continuous body of the substantially same material. In this case, the body BD may be provided by using the half-finished probe product 20 having the conductive material 6 in the anodic aluminum oxide mold 1 having the continuous through-holes 1a.

The half-finished probe product 20 may have the conductive material 6 made of the metal paste or metal powder so that the conductive material 6 may be simultaneously charged in the through-holes 1a by being pushed by the pressing means 5. This may enable the manufacturing process for forming the body BD to be efficiently performed.

The half-finished probe product 20 according to the present disclosure may enable the process of separately manufacturing the probe 40 to be quickly performed. This may result in improving production speed of the MEMS probe card 30 formed by separately manufacturing the probe 40 and joining the probe 40 to the multilayer wiring substrate 12.

As described above, the present disclosure has been described with reference to the exemplary embodiments. However, those skilled in the art will appreciate that various modifications, additions and substitutions are possible, without departing from the scope and spirit of the present disclosure as disclosed in the accompanying claims.

What is claimed is:

1. An anodic aluminum oxide mold configured so that a plurality of unit anodic aluminum oxide sheets each having a through-hole are joined from top to bottom, and the respective through-holes of the unit anodic aluminum oxide sheets communicate with each other to define an internal space.

2. The anodic aluminum oxide mold of claim 1, wherein a surface of the anodic aluminum oxide mold is configured as a barrier layer of each of the unit anodic aluminum oxide sheets.

3. The anodic aluminum oxide mold of claim 1, wherein each of the unit anodic aluminum oxide sheets is composed of a plurality of anodic aluminum oxide layers joined by a junction layer.

4. A half-finished probe product, comprising:
an anodic aluminum oxide mold configured so that a plurality of unit anodic aluminum oxide sheets each having a through-hole are joined from top to bottom, and the respective through-holes of the unit anodic aluminum oxide sheets communicate with each other to define an internal space; and
a conductive material provided in the through-holes.

5. The half-finished probe product of claim 4, further comprising: a conductive tip provided on a surface of the conductive material.

6. A probe card, comprising:
a multilayer wiring substrate made of an anodic aluminum oxide film, having a vertical wiring part and a horizontal wiring part therein, and having a probe connection pad on a surface thereof; and
a body connected to the probe connection pad and configured as a single continuous body of a substantially same material.
